(19) United States
(12) Patent Application Publication
(10) Pub. No.: US 2005/0264308 A1
(43) Pub. Date: Dec. 1, 2005

(54) Test board locking device including stiffener

(75) Inventor: Seung-Hoon Jun, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/099,085

(22) Filed: Apr. 5, 2005

(30) Foreign Application Priority Data
May 31, 2004 (KR) 04-39025

(51) Int. Cl. G01R 31/02

(52) U.S. Cl. 324/754

(57) ABSTRACT

A test board locking device includes a stiffener having a plurality of spaced-apart fix bars. A test board has first fix holes each corresponding to the fix bars adapted for coupling to the stiffener. A lid has second fix holes each corresponding to the fix bars, the lid adapted for coupling the test board to the stiffener. The fix bars extend from the stiffener and are coupled to the stiffener such that rotation of each fix bar in a first direction causes the fix bar to be raised relative to the stiffener and rotation of each fix bar in a second direction causes the fix bar to be lowered relative to the stiffener.

### RELATED APPLICATIONS

This application claims priority to Korean Patent Application No. 2004-39025, filed on May 31, 2004 in the Korean Intellectual Property Office, the disclosure of which is incorporated herein in its entirety by reference.

### BACKGROUND OF THE INVENTION

1. Field of the Invention

The present invention relates to a test board locking device for test of semiconductor chips and, more particularly, to a test board locking device which is readily removable/attachable from/to a stiffener in an electrical die sorting (EDS) process during the formation of semiconductor chips.

2. Description of Related Art

Semiconductor chips formed on a wafer using multiple semiconductor processes are assembled in a package that may be made of various materials and have various shapes. In an electrical die sorting (EDS) process, an electrical signal is applied to each pad of an unassembled chip to test whether the chip is operable or inoperable. Since inoperable chips are determined in advance using the EDS process, any unnecessary cost associated with performing a packaging process on the inoperable chips is reduced and process defects are eliminated prior to manufacture. In order to achieve these advantages of the EDS process, a test board with metallic patterns is used to contain a semiconductor chip therein and to apply an electrical signal for testing each pad of the contained semiconductor chip. Such a test board is fixed onto a stiffener and is mounted at a mounting unit disposed at a test head of a test device to be tested.

As illustrated in FIG. 1, a conventional test board locking device used to test semiconductor chips comprises a mounting unit 100, a stiffener 110, and a test board 120 in which a semiconductor chip for test is contained. The mounting unit 100, the stiffener 110, and the test board 120 are mounted on a header of a test apparatus.

The mounting unit 100 has three bearing guide grooves 102a, 102b, and 102c, a control bar 104, and a rotatable bowl 106. The stiffener 110 has bearings 112a, 112b, and 112c each corresponding to the bearing guide 15 grooves 102a, 102b, and 102c of the mounting unit 100, a plurality of first fix grooves 114, and a handle 116. The test board 120 has second fix grooves 124 each corresponding to the first fix grooves 114 of the stiffener 110.

The stiffener 110 is fixed to the inside of the rotatable bowl 106. The bearings 112a, 112b, and 112c of the stiffener 110 are inserted into the bearing 20 guide grooves 102a, 102b, and 102c of the mounting unit 100, respectively. The rotatable bowl 106 is rotated using the control bar 104, fixing the stiffener 110 to the mounting unit 100. The test board 120 is mounted on the stiffener 110 such that the second fix grooves 124 match the first fix grooves 114 on the stiffener 110, respectively. Further, the test board 120 is coupled to the stiffener 110 via screws 122 through the second fix grooves 124 and the first fix grooves 114 to be fixed on the stiffener 110.

Test boards having different metallic patterns are used according to the type of semiconductor chips under test. Therefore, in the event that a certain type of semiconductor chip is replaced in the test apparatus, the test board must also be replaced. In the case of the conventional test board format utilizing screws for securing the test board to the mounting unit, screwing and unscrewing operations must be repeated by a handler. Although the number of screws varies with the type of test boards, at least 70 screws are generally used. For this reason, this test board replacement process has a negative impact on processing efficiency.

FIG. 2 illustrates another conventional test board locking device implemented to reduce the amount of time needed for replacing the test board, which is disclosed in Korean Patent Application No. 2003-0084188, published on Nov. 1, 2003. Unlike the screw-based coupling approach described above with reference to FIG. 1, a separate fix ring 230 is used to fix a test board 220 and a stiffener 210 onto a mounting unit 200 disposed at a test head of a test device. The mounting unit 200 has three bearing guide grooves 202a, 202b, and 202c and a control bar 206, and three third fix grooves 204. The stiffener 210 has bearing insert grooves 212a, 212b, and 212c each corresponding to the bearing guide grooves 202a, 202b, and 202c of the mounting unit 200, fourth fix grooves 214 each corresponding to the third fix grooves 204 of the mounting unit 200, two insert protrusions 215a and 215b, and a handle 216. The test board 220 has first insert protrusion-receiving grooves 225a and 225b each corresponding to the insert protrusions 215a and 25 lb of the stiffener 210. The fix ring 230 has second insert protrusion-receiving grooves 235a and 235b each corresponding to the insert protrusions 215a and 215b of the stiffener 230 and bearings 234 each corresponding to the bearing guide grooves 202a, 202b, and 202c of the mounting unit 200.

The stiffener 210 is disposed in a rotatable bowl 208 of the mounting unit 200. The bearing insert grooves 212a, 212b, and 212c and the fourth fix grooves 214 of the stiffener 210 are disposed to correspond to the bearing guide grooves 202a 202b, and 202c and the third fix grooves 204 formed at the rotatable bowl 208 of the mounting unit 200, respectively. The stiffener 210 is coupled to screws 217 through the fix grooves 204 and 214 to be fixed to the rotatable bowl 208 of the mounting unit 200. The test board 220 is disposed over the stiffener 210 such that the first insert protrusion-receiving grooves 225a and 225b receive the insert protrusions 215a and 215b of the stiffener 210, respectively. The insert protrusions 215a and 215b of the stiffener 210 protrude through the first insert protrusion-receiving grooves 225a and 225b of the test board 220. The fix ring 230 locates the second insert protrusion-receiving grooves 235a and 235b to each receive the insert protrusions 215a and 215b and locates a bearing 234 at the mounting unit 200 through the bearing insert grooves 212a, 212b, and 212c of the stiffener 210 and the bearing guide grooves 202a, 202b, and 202c of the rotatable bowl 208. The stiffener 210 is fixed to the inside of the rotatable bowl 208 of the mounting unit 200 by handling the control bar 206 attached to the rotatable bowl, tightly fixing the stiffener 210 and the test board 220 to each other.

The test board locking device shown in FIG. 2 greatly reduces processing time for replacing the test board, as compared to the test board locking device shown in FIG. 1. Nevertheless, the configuration of FIG. 2 still requires manual performance of screwing and unscrewing operations and the unit is relatively complex in structure.

### SUMMARY OF THE INVENTION

The present invention is directed to a test board locking device for readily removing and attaching a test board mounted to a test device for testing a semiconductor chip.

The present invention is further directed to a test board locking device for tightly fixing a test board onto a stiffener irrespective of the type of test board.

In one aspect, the test board locking device includes a stiffener having a plurality of spaced-apart fix bars. A test board has first fix holes each corresponding to the fix bars adapted for coupling to the stiffener. A lid has second fix holes each corresponding to the fix bars, the lid adapted for coupling the test board to the stiffener. The fix bars extend from the stiffener and are coupled to the stiffener such that rotation of each fix bar in a first direction causes the fix bar to be raised relative to the stiffener and rotation of each fix bar in a second direction causes the fix bar to be lowered relative to the stiffener.

In one embodiment, the fix bars are coupled to the stiffener at a threaded interface. Each of the fix bars has a base with a male thread that mates with a female hole formed in the stiffener. Adjustment of the height of the fix bars by raising and lowering them allows for secure locking of test boards of varying thicknesses.

In another embodiment, the lid has a central aperture that allows for access to a surface of the test board.

In another embodiment, the stiffener comprises: a base; and an inner ring fixed onto the base, wherein the fix bars are positioned to extend from a top surface of the inner ring. The stiffener optionally further comprises at least two handles that are attached to an edge of the base.

In another embodiment, the test board locking device further comprises a test head mounting unit and the stiffener further comprises a plurality of protrusions which are disposed at an outer lateral face of the lower unit and are inserted into corresponding guide grooves formed on the test head mounting unit.

In another embodiment, each fix bar comprises: a lower bar partially inserted into the stiffener; an upper bar extending from the lower bar; and a connector for connecting the upper bar to the lower bar. In one example, the connector comprises a pin such that the lower bar and upper bar have a hinged interface. A portion of the lower bar is threaded, and mates with a corresponding threaded hole in the stiffener.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is an exploded perspective view of a conventional test board device for fixing a test board onto a stiffener using screws.

FIG. 2 is an exploded perspective view of a conventional test board device for fixing a test board to a stiffener using a separate fix ring.

FIG. 3 is an exploded perspective view of a test board locking device according to the present invention.

FIG. 4 is a cross-sectional view showing one of fix bars disposed on a stiffener shown in FIG. 3, in accordance with the present invention.

FIG. 5 is a cross-sectional view showing a coupling procedure after a test board and a lid are coupled onto the stiffener, in accordance with the present invention.

FIG. 6 is a top plan view showing a fixing procedure after the test board and the lid are coupled to the stiffener, in accordance with the present invention.

FIG. 7 is a cross-sectional view showing that the test board and the lid are tightly fixed onto the stiffener using the steps of FIG. 5 and FIG. 6, in accordance with the present invention.

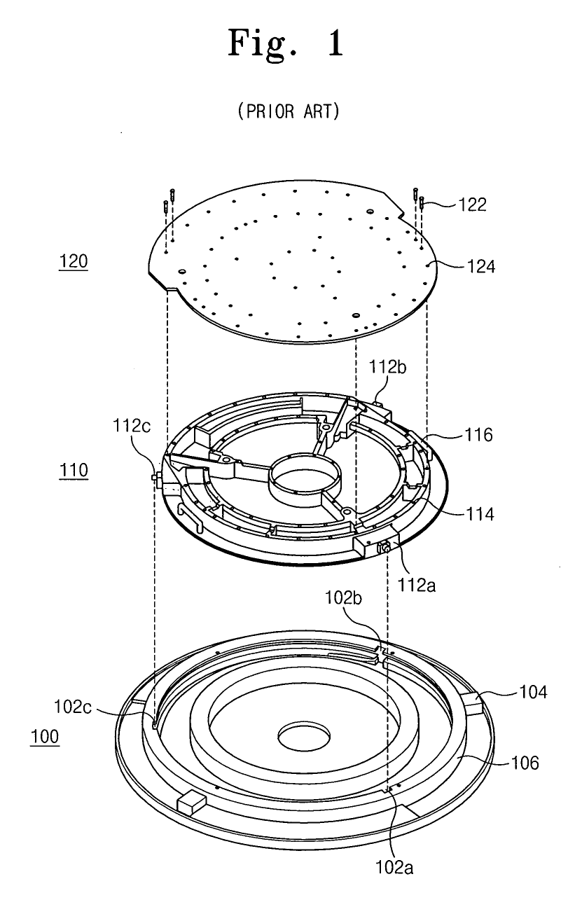

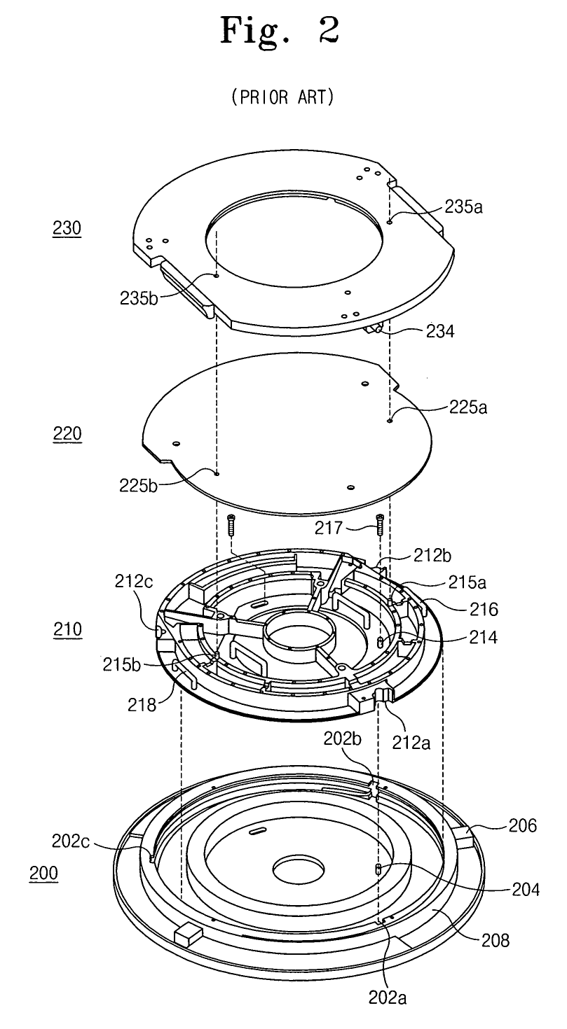

### DETAILED DESCRIPTION OF THE INVENTION

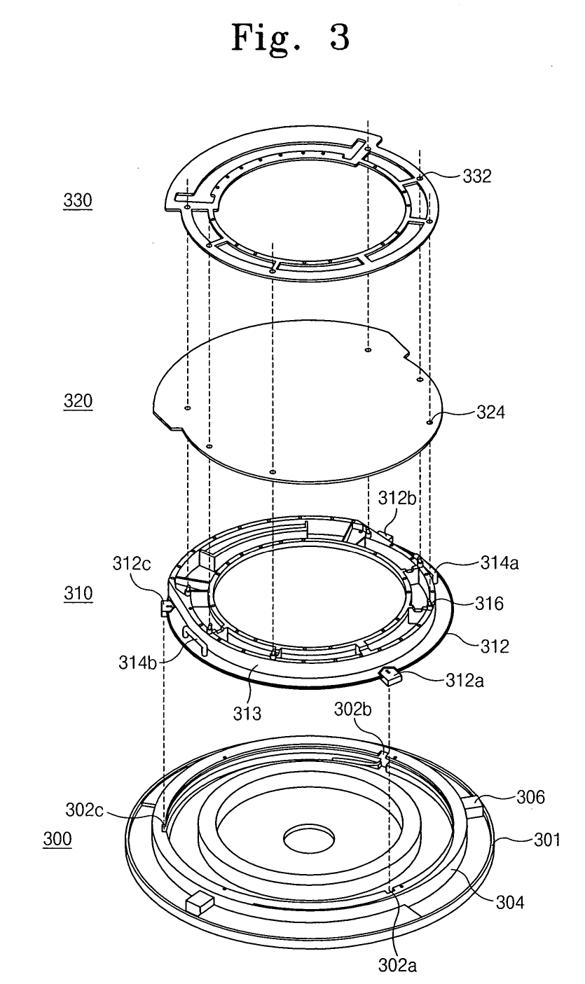

As illustrated in FIG. 3, a test board locking device according to the present invention comprises a mounting unit 300, a stiffener 310, a test board 320, and a lid 330.

The mounting unit 300 is included in a test head of a test apparatus and has a first lower part 301, a rotatable bowl 304, a plurality of control bars 306, and three guide grooves 302a, 302b, and 302c. The rotatable bowl 304 is disposed on the first lower part 301 and is rotatable at a predetermined angle. The control bars 306 are protrudingly attached to an outer lateral face of the rotatable bowl 304 to readily handle a rotation of the rotatable bowl 304. The three guide grooves 302a, 302b, and 302c are formed on a top surface of the rotatable bowl 304 in regular intervals. Each of the grooves 302a, 302b, and 302c is connected to a furrow formed on an inner lateral face of the rotatable bowl 304.

The stiffener 310 has a second lower part 312 and an inner ring 313. The second lower part 312 has the same size as the inside of the rotatable bowl 304 and is a donut-shaped, or circular, structure. Two handles 314a and 314b are symmetrically attached to the edge on the second lower part 312 to readily move the stiffener 310. Three protrusions 312a, 312b, and 312c are attached to an outer lateral face of the second lower part 312, each corresponding to one of the guide grooves 302a, 302b, 302c of the rotatable bowl 304. An internal ring having a predetermined height and width is fixedly disposed at the center on the second lower part 302. Six fix bars 316 are attached to a top surface of the inner ring 313, and are spaced at regular intervals.

The test board 320 is located on the inner ring 313 to be fixed. In this regard, first fix holes 324 are formed on the test board 320, each corresponding to the fix bars 316 attached to the inner ring 313.

The lid 330 is shaped and sized to match the size and shape of the test board 320. Second fix holes 332 are formed on the lid 330, each corresponding to the first fix holes 324 of the test board 320. An inner aperture is provided in a central portion of the lid 330 to allow for external access to the test board. For example, the aperture makes it possible to accomplish a probe connection for applying an electrical signal to an upper surface of the test board 320.

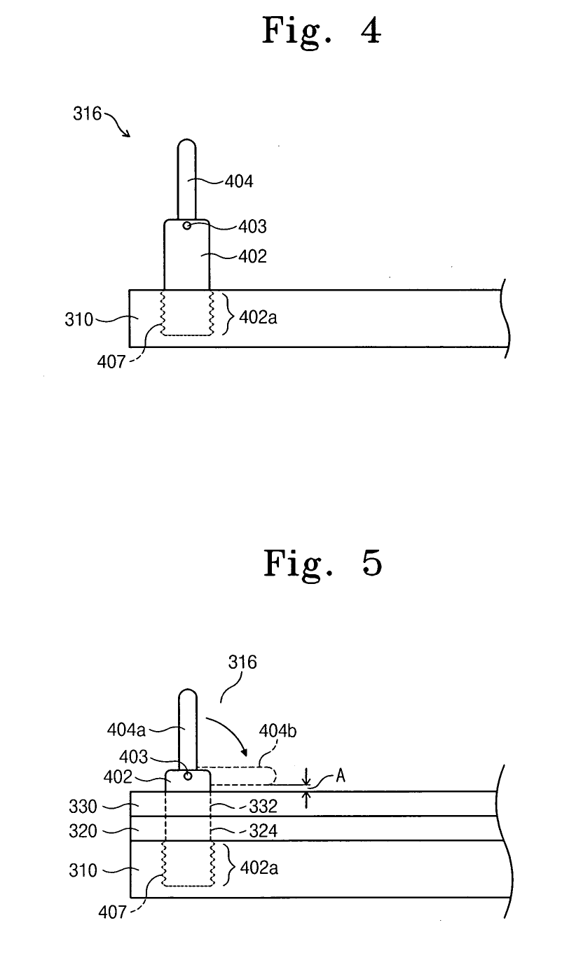

FIG. 4 is a cross-sectional view showing one of fix bars 316 provided on the stiffener shown in FIG. 3. As illustrated in FIG. 4, a fix bar 316 includes a lower bar 402 and an upper bar 404. The lower bar 402 is inserted into a top surface of an inner ring 312, for example at a threaded coupling comprising a female threaded hole 407 in the stiffener body 310 and a corresponding male threaded base on a lower portion 402a of the lower base 402. The upper bar 404 is connected to the lower bar 402 by a connector 403, for example comprising a pin or hinge, and extends in a perpendicular direction from body of the stiffener. The connector 403 comprises a hinge such that the upper bar 404 is pivotable with respect to the lower bar 402. Since a lower portion 402a of the lower bar 402 is threaded, rotation of the lower bar 402 enables the fix bar 316 to be raised and lowered with respect to the stiffener body 310.

FIG. 5 is a cross-sectional view showing a coupling procedure after a test board 320 and a lid 330 are coupled onto the stiffener. Referring to FIG. 5, a test board 320 and a lid 330 are coupled onto a stiffener 310 by inserting fix bars 316 of the stiffener 310 into fix holes formed at each of the test board 320 and the lid 330. An upper bar 404 of the respective fix bars 316 is turned at a predetermined angle to press the lid 330, so that the test board 320 and the lid 330 adhere closely onto the stiffener 310. However, a space A is made between the turned upper bar 404b and the lid 330 according to a kind of the test board 320 to cause an instable contact of the test board 320 with a probe of a test apparatus. Due to the instable contact of the test board 320, the reliability of test results may be adversely affected. Thus, the present invention provides means for closely adhering and fixing a test board onto a stiffener irrespective of the type of test board by allowing for continuous adjustment of the height of the fix bars 316.

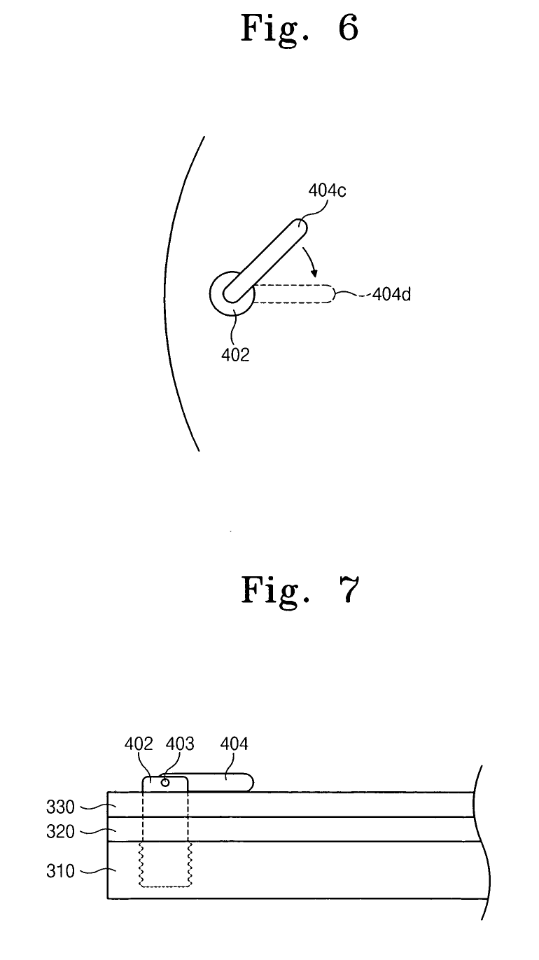

FIG. 6 is a top plan view showing a fixing procedure after the test board and the lid are coupled onto the stiffener.

As illustrated in FIG. 6, turning of the upper bar 404a, for example, from a first position 404c to a second position 404d causes a change in the vertical position of the fix bar 316 relative to the stiffener body 310. In this example, the upper bar is rotated in a clockwise direction to lower the body of the fix bar 316 deeper into the threaded hole of the stiffener 310. Following the rotation, the applied test board 320 is tightly fixed onto the stiffener 310, as illustrated in FIG. 7. This configuration accommodates variation in the thicknesses of the test boards 320, allowing for flexibility in the height of the fix bars 316 with respect to the stiffener 310 over a continuous range of heights. Thus, the present invention accommodates test boards over a range of thicknesses.

While this invention has been particularly shown and described with references to preferred embodiments thereof, it will be understood by those skilled in the art that various changes in form and details may be made herein without departing from the spirit and scope of the invention as defined by the appended claims.

1. A test board locking device for a test head of a semiconductor test apparatus, comprising:
a stiffener having a plurality of spaced-apart fix bars;
a test board having first fix holes each corresponding to the fix bars adapted for coupling to the stiffener; and
a lid having second fix holes each corresponding to the fix bars, the lid adapted for coupling the test board to the stiffener,
wherein the fix bars extend from the stiffener and are coupled to the stiffener such that rotation of each fix bar in a first direction causes the fix bar to be raised relative to the stiffener and rotation of each fix bar in a second direction causes the fix bar to be lowered relative to the stiffener.

2. The test board locking device of claim 1, wherein the fix bars are coupled to the stiffener at a threaded interface.

3. The test board locking device of claim 1, wherein each of the fix bars has a base with a male thread that mates with a female hole formed in the stiffener.

4. The test board locking device of claim 1, wherein the raising and lowering of the fix bars allows for secure locking of test boards of varying thicknesses.

5. The test board locking device of claim 1, wherein the lid has a central aperture that allows for access to a surface of the test board.

6. The test board locking device of claim 1, wherein the stiffener comprises:
a base; and
an inner ring fixed onto the base,
wherein the fix bars are positioned to extend from a top surface of the inner ring.

7. The test board locking device of claim 6, wherein the stiffener further comprises at least two handles that are attached to an edge of the base.

8. The test board locking device of claim 6, further comprising a test head mounting unit and wherein the stiffener further comprises a plurality of protrusions which are disposed at an outer lateral face of the lower unit and are inserted into corresponding guide grooves formed on the test head mounting unit.

9. The test board locking device of claim 1, wherein each fix bar comprises:
a lower bar partially inserted into the stiffener;
an upper bar extending from the lower bar; and
a connector for connecting the upper bar to the lower bar.

10. The test board locking device of claim 9 wherein the connector comprises a pin such that the lower bar and upper bar have a hinged interface.

11. The test board locking device of claim 9, wherein a portion of the lower bar is threaded, and mates with a corresponding threaded hole in the stiffener.
